(19) United States
(12) Patent Application Publication
(10) Pub. No.: US 2015/0049448 A1
(43) Pub. Date: Feb. 19, 2015

(54) SEMICONDUCTOR DEVICE

(71) Applicant: KABUSHIKI KAISHA TOSHIBA, Minato-ku (JP)

(72) Inventors: Hironari UEHARA, Kamakura-shi (JP); Shiro Harashima, Sagamihara-shi (JP)

(73) Assignee: KABUSHIKI KAISHA TOSHIBA, Minato-ku (JP)

(21) Appl. No.: 14/142,225

(22) Filed: Dec. 27, 2013

Related U.S. Application Data
(60) Provisional application No. 61/865,406, filed on Aug. 13, 2013.

(51) Int. Cl. H05K 1/18

(52) U.S. Cl. CPC H05K 1/181
USPC 361/767

(57) ABSTRACT

According to one embodiment, a semiconductor device includes a board, a controller, a first line, a second line, and a pad. The board includes a first external terminal and a second external terminal. The controller is on the board. The first line extends between the first external terminal and the controller. The second line extends between the second external terminal and the controller. The pad is to be electrically connected to the second line and to be a part of a waveform adjustment circuit that makes a waveform of a signal flowing through the second line more similar to a waveform of a signal flowing through the first line.

### CROSS-REFERENCE TO RELATED APPLICATIONS

This application claims the benefit of U.S. Provisional Application No. 61/865,406, filed Aug. 13, 2013, the entire contents of which are incorporated herein by reference.

### FIELD

Embodiments described herein relate generally to semiconductor devices.

### BACKGROUND

Semiconductor devices mounted with semiconductor memory chips are provided.

A shorter development period is desired for semiconductor devices.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a plan view schematically showing an inside of a semiconductor device according to a first embodiment;

FIG. 2 is a sectional view schematically showing a module shown in FIG. 1;

FIG. 3 is a plan view schematically showing a relationship between external terminals and a controller of the module shown in FIG. 1;

FIG. 4 is a sectional view schematically showing a first line of the module shown in FIG. 3;

FIG. 5 is a sectional view schematically showing a second line of the module shown in FIG. 3;

FIG. 6 is a diagram schematically showing an example of waveforms of signals of the module shown in FIG. 3 (state in which a capacitor is not mounted);

FIG. 7 is a diagram schematically showing an example of a waveform adjustment circuit shown in FIG. 3;

FIG. 8 is a diagram schematically showing an example of waveforms of the signals of the module shown in FIG. 2 (state in which the capacitor is mounted);

FIG. 9 is a plan view schematically showing a module of a semiconductor device according to a second embodiment;

FIG. 10 is a plan view schematically showing the relationship between a controller and a semiconductor chip of the module shown in FIG. 9;

FIG. 11 is a sectional view schematically showing a first line of the module shown in FIG. 10;

FIG. 12 is a sectional view schematically showing a second line of the module shown in FIG. 10;

FIG. 13 is a diagram schematically showing an example of waveforms of signals of the module shown in FIG. 10 (state in which a capacitor is not mounted);

FIG. 14 is a diagram schematically showing an example of a waveform adjustment circuit shown in FIG. 10;

FIG. 15 is a diagram schematically showing an example of waveforms of the signals of the module shown in FIG. 10 (state in which the capacitor is mounted);

FIG. 16 is a plan view schematically showing the relationship between a controller and a semiconductor chip of a module of a semiconductor device according to a third embodiment;

FIG. 17 is a sectional view schematically showing a first line of the module shown in FIG. 16;

FIG. 18 is a sectional view schematically showing a second line of the module shown in FIG. 16;

FIG. 19 is a diagram schematically showing an example of waveforms of signals of the module shown in FIG. 16 (state in which a register is not mounted);

FIG. 20 is a diagram schematically showing an example of a waveform adjustment circuit shown in FIG. 16; and

FIG. 21 is a diagram schematically showing an example of waveforms of the signals of the module shown in FIG. 16 (state in which the register is mounted).

### DETAILED DESCRIPTION

Various embodiments will be described hereinafter with reference to the accompanying drawings.

In general, according to one embodiment, a semiconductor device comprises a board, a controller, a first line, a second line, and a pad. The board comprises a first external terminal and a second external terminal. The controller is on the board. The first line extends between the first external terminal and the controller. The second line extends between the second external terminal and the controller. The pad is to be electrically connected to the second line and to be a part of a waveform adjustment circuit that makes a waveform of a signal flowing through the second line more similar to a waveform of a signal flowing through the first line.

In this specification, some components are expressed by two or more terms. Those terms are just examples. Those components may be further expressed by another or other terms. And the other components which are not expressed by two or more terms may be expressed by another or other terms.

The drawings are schematically illustrated. In the drawings, in some cases, the relationship between a thickness and planar dimensions or the scale of the thickness of each layer may be different from the actual relationship or scale. In addition, in the drawings, components may have different dimensions or scales.

### First Embodiment

FIGS. 1 to 8 show a semiconductor device 1 according to the first embodiment. The semiconductor device 1 is, for example, a semiconductor storage device and, for example, a NAND flash memory. An example of the semiconductor device 1 is an SD (trademark) memory card, but is not limited to the SD memory card.

FIG. 1 shows an inside of the semiconductor device 1. As shown in FIG. 1, the semiconductor device 1 includes a case 2 and a module 3 (e.g., a semiconductor module) accommodated in the case 2.

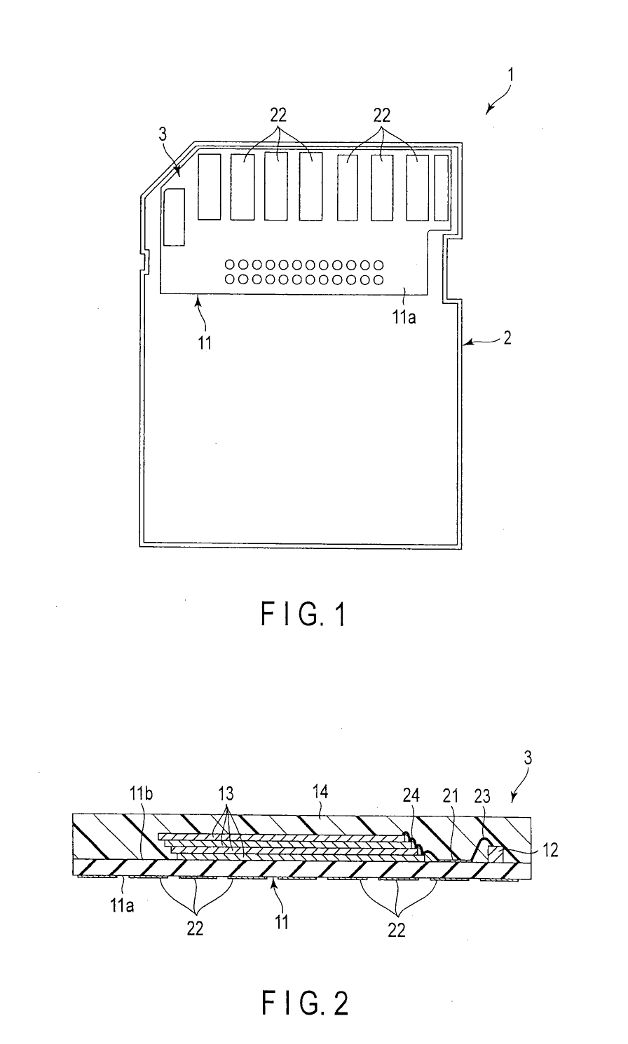

FIG. 2 shows a cross section of the module 3. The module 3 is a so-called SiP (System in Package) and includes a board 11, a controller 12, a plurality of semiconductor chips 13, and a sealing portion 14.

As shown in FIG. 2, the board 11 (e.g., a wiring board) includes a substrate made of, for example, glass epoxy resin and a wiring pattern 21 provided on the substrate. The wiring pattern 21 includes wiring patterns 21a, 21b, 21c, 21d described later.

The board 11 includes a first surface 11a (e.g., an external terminal surface) and a second surface 11b (e.g., a mounting surface) positioned on the opposite side of the first surface 11a. The first surface 11a and the second surface 11b are substantially parallel to each other and each extends in an extension direction of the board 11.

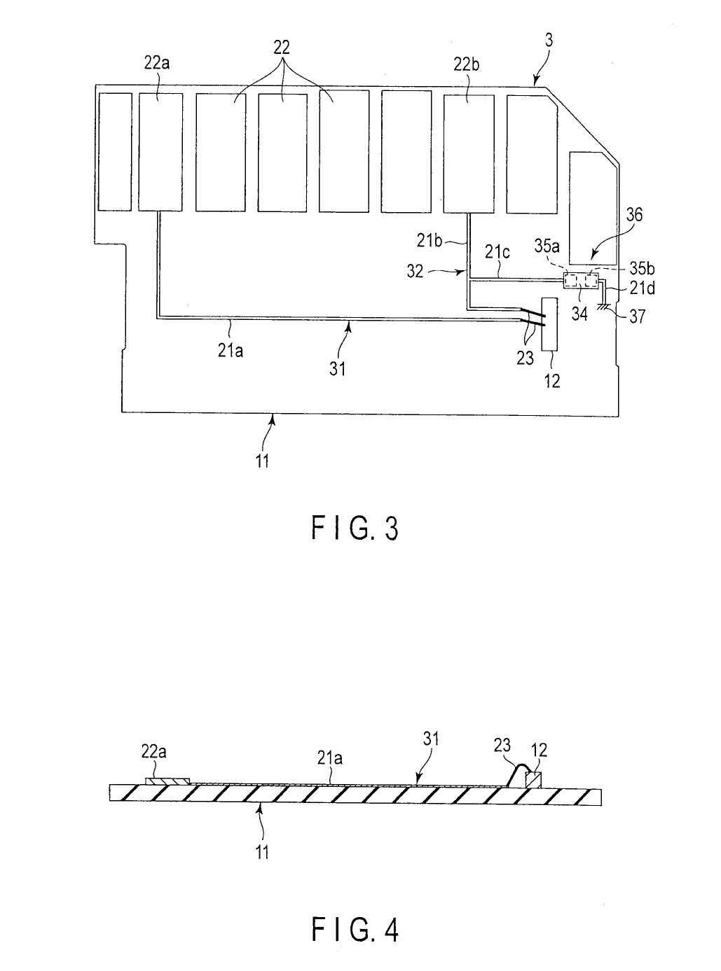

As shown in FIGS. 1 and 2 a plurality of external terminals 22 (i.e., external connection terminals, e.g., SD terminals) is provided on the first surface 11a of the board 11. The external terminals 22 are arranged following the standard of, for example, the SD memory card. The external terminals 22 are exposed to the outside of the case 2 (i.e., the outside of the semiconductor device 1). The external terminals 22 are to be electrically connected to connectors of a host on which the semiconductor device 1 is mounted. The plurality of external terminals 22 includes a first external terminal 22a and a second external terminal 22b (see FIG. 3).

As shown in FIG. 2, the wiring pattern 21 is provided on the second surface 11b of the board 11. The controller 12 (e.g., a controller chip) is mounted on the second surface 11b of the board 11. The controller 12 is an example of each of the “component”, “electronic component”, and “semiconductor chip”.

The controller 12 controls the operation of the semiconductor chips 13. The controller 12 writes, reads, or erases data of the semiconductor chips 13 in accordance with a command, for example, from outside (e.g., the host) to manage the storage state of the semiconductor chips 13. The controller 12 is electrically connected to the second surface 11b of the board 11 through a bonding wire 23.

As shown in FIG. 2, the plurality of semiconductor chips 13 is mounted on the second surface 11b of the board 11. The semiconductor chips 13 are piled up each other on the second surface 11b of the board 11. Each of the semiconductor chips 13 is, for example, any memory chip and, for example, a NAND flash memory. The semiconductor chip 13 is electrically connected to the second surface 11b of the board 11 through a bonding wire 24.

As shown in FIG. 2, the semiconductor device 1 includes the sealing portion 14 (i.e., a resin portion, mold, or mold resin portion). An example if the sealing portion 14 is a resin (i.e., an epoxy resin). The sealing portion 14 integrally covers (i.e., integrally seals) the second surface 11b of the board 11, the controller 12, the semiconductor chip 13, and the bonding wires 23, 24. The sealing portion 14 forms an outer shape of the package of the semiconductor device 1.

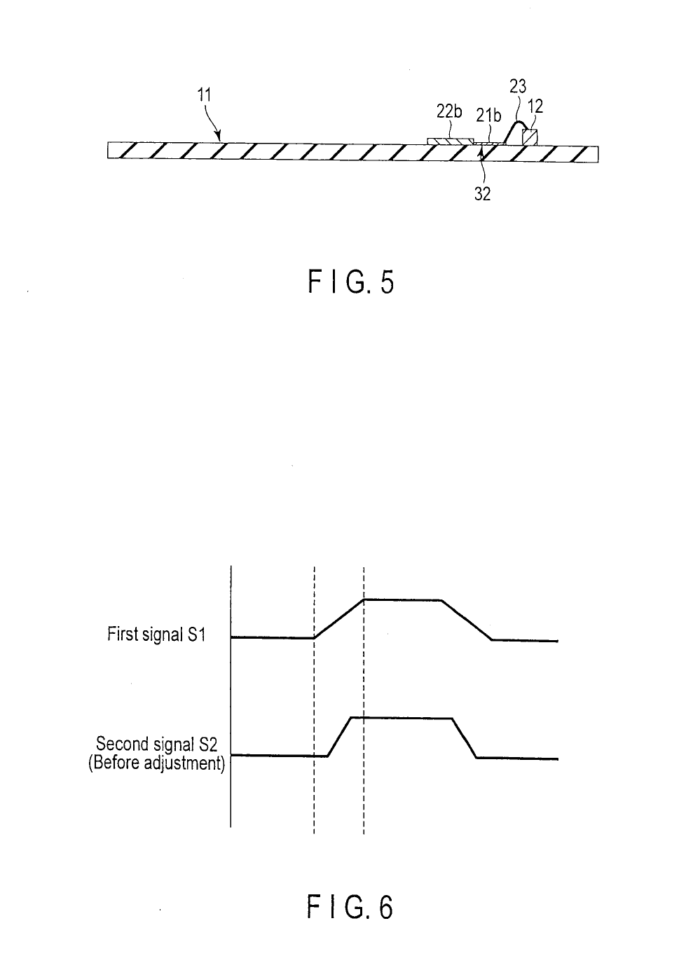

FIG. 3 schematically shows the relationship between the external terminals 22 and the controller 12. FIG. 4 schematically shows a first line 31 of the module 3. FIG. 5 schematically shows a second line 32 of the module 3. In FIGS. 3 to 5, for convenience of description, the external terminals 22 and the controller 12 are depicted and shown on one surface of the board 11.

As shown in FIG. 3, the first line 31 (e.g., a first wire or first signal line) extends between the first external terminal 22a and the controller 12. The first line 31 is connected to the first external terminal 22a and the controller 12 to electrically connect the first external terminal 22a and the controller 12. The first line 31 includes the wiring pattern 21a and the bonding wire 23 extending between the first external terminal 22a and the controller 12.

Similarly, the second line 32 (e.g., a second wire or second signal line) extends between the second external terminal 22b and the controller 12. The second line 32 is connected to the second external terminal 22b and the controller 12 to electrically connect the second external terminal 22b and the controller 12. The second line 32 includes the wiring pattern 21b and the bonding wire 24 extending between the second external terminal 22b and the controller 12.

As shown in FIGS. 3 to 5, the first external terminal 22a is positioned farther from the controller 12 than the second external terminal 22b. Thus, the first line 31 is longer than the second line 32. A waveform of a signal flowing through the board 11 is more weakened with an increasing distance through which the signal flows. That is, for a pulse signal, a rise of a pulse becomes gentler with an increasing distance through which the pulse flows.

FIG. 6 shows an example of waveforms of signals when a capacitor 34 described later is not mounted. A first signal S1 is an example of a signal input into the controller 12 after flowing through the first line 31 from the first external terminal 22a. A second signal S2 is an example of a signal input into the controller 12 after flowing through the second line 32 from the second external terminal 22b. Incidentally, FIGS. 6 and 8 show waveforms of the first signal S1 and the second signal S2, for example, in the instant of being input into the controller 12.

As shown in FIG. 6, the first signal S1 flowing through the relatively long first line 31 is weakened in the processing of flowing through the first line 31. On the other hand, the signal S2 flowing through the second line 32 becomes a relatively sharp pulse signal.

Thus, when the capacitor 34 is not mounted, a rise of the first signal S1 (e.g., a first pulse signal) is gentler than a rise of the second signal (e.g., a second pulse signal). For example, even if the second signal S2 starts the rise in the timing substantially simultaneously with or delayed from a start of rise of the first signal S1, the rise of the second signal S2 may be completed before the rise of the first signal S1 is completed.

Here, there is a state in which the controller 12 becomes capable of receiving the second signal S2 input from the second line 32 after the first signal S1 input from the first line 31 rises to a predetermined level or more in at least one piece of processing. Thus, if the rise of the first signal S1 is delayed when compared with the rise of the second signal S2, the second signal S2 may not be received by the controller 12.

Therefore, as shown in FIG. 3, the second surface 11b of the board 11 according to the present embodiment includes a pair of pads 35a, 35b. The pads 35a, 35b are to be electrically connected to the second line 32 and to be a part of a waveform adjustment circuit 36 that makes a waveform of the second signal S2 flowing through the second line 32 more similar to a waveform of the first signal S1 flowing through the first line 31.

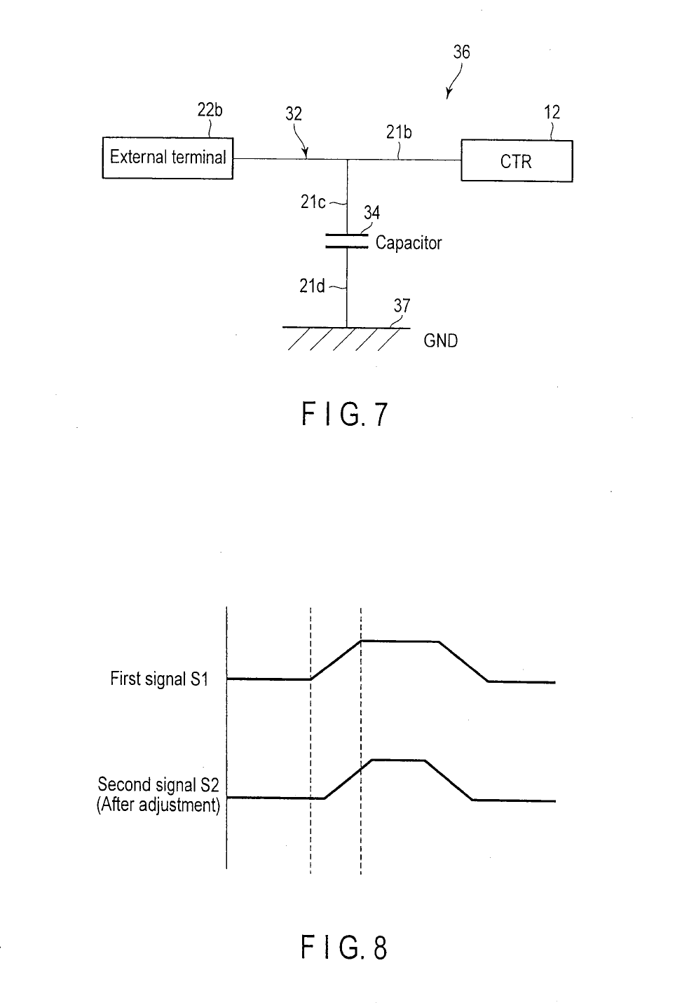

FIG. 7 shows an example of the waveform adjustment circuit 36. As shown in FIGS. 3 and 7, the pads 35a, 35b can receive the capacitor 34 mounted thereon as an option when a waveform adjustment (e.g., a waveform timing adjustment) is needed. That is, the pads 35a, 35b are so-called spare pads and remain in the product as empty pads when the waveform adjustment is not needed.

More specifically, as shown in FIGS. 3 and 7, the one pad 35a is connected in parallel between the second external terminal 22b and the controller 12. That is, the pad 35a is electrically connected to the second line 32 via the wiring pattern 21c. On the other hand, the other pad 35b is electrically connected to a ground 37 via another wiring pattern 21d.

When a waveform adjustment is needed, the waveform adjustment circuit 36 is added by the capacitor 34 being mounted on the pads 35a, 35b. An example of the waveform adjustment circuit 36 is configured by the pads 35a, 35b, the capacitor 34, and the wiring patterns 21c, 21d of the board 11.

The capacitor 34 is connected in parallel between the second external terminals 22b and the controller 12 via the pads 35a, 35b. The capacitor 34 makes a rise of a pulse signal flowing through the second line 32 gentler. As an example, the capacitor 34 makes the rise gentler such that the rise of the pulse signal flowing through the second line 32 is substantially simultaneous with or delayed from a rise of a pulse signal flowing through the first line 31.

FIG. 8 shows an example of waveforms of signals when the capacitor 34 is mounted. In the present embodiment, if, as shown in FIG. 8, the second signal S2 starts to rise in the timing substantially simultaneous with or delayed from a start of rise of the first signal S1, the rise of the second signal S2 is completed in the timing substantially simultaneous with or delayed from the completion of rise of the first signal S1.

Accordingly, for example, the controller 12 first checks whether the first signal S1 is input and then becomes capable of receiving the second signal S2 in at least one piece of processing. The controller 12 receives the second signal S2 in this state and performs processing based on the second signal S2.

Next, the operation of the semiconductor device 1 according to the present embodiment will be described.

In the development of the semiconductor device 1, the board is generally designed based on a simulation and then whether the actual semiconductor device 1 operates just as simulated is verified. If the semiconductor device 1 does not operate just as simulated, the board needs to be re-designed.

At the signal speed of the semiconductor device 1 in the past, a certain timing margin can be ensured and thus, a simulation in the stage of board design and an operation of the actual semiconductor device 1 frequently match and there are not many cases when the board needs to be re-designed.

For the semiconductor device 1 in the future, however, with the increasing speed and larger capacities, a further speedup (e.g., input/output by a sharper pulse signal) of a signal flowing through the board 11 is desired. If the signal is made still faster, it is no longer easy to ensure timing margins and it becomes difficult to synchronize the timing of, for example, a plurality of signals. Thus, a case when a simulation in the stage of board design and an operation of the actual semiconductor device 1 do not match may arise and cases when the board needs to be re-designed are expected to increase. Re-designing the board makes it difficult to shorten the development period.

Thus, the semiconductor device 1 according to the present embodiment has the pads 35a, 35b to be a part of the waveform adjustment circuit 36 provided on the board 11 in advance. Then, when the semiconductor device 1 does not operate as designed due to, for example, signal timing shifts, the waveform adjustment circuit 36 can be added by mounting an additional component (e.g., the capacitor 34) on the pads 35a, 35b. By providing the waveform adjustment circuit 36, the timing of the signal S2 flowing through the second line 32 can be adjusted and the semiconductor device 1 can be caused to operate as designed.

That is, according to the semiconductor device 1 in the present embodiment, even if a simulation in the stage of board design and an operation of the actual semiconductor device 1 do not match, the semiconductor device 1 can be made to operate as expected by adding the capacitor 34 to make a timing adjustment of a signal without re-designing the board. Accordingly, the development period of the semiconductor device 1 can be shortened.

In the present embodiment, the capacitor 34 that makes a rise of a pulse signal flowing through the second line 32 gentler can be mounted on the pads 35a, 35b. According to such a configuration, problems caused by the rise timing of a pulse signal can be adjusted.

In the present embodiment, the capacitor 34 makes the rise gentler such that the rise of the pulse signal flowing through the second line 32 is substantially simultaneous with or delayed from a rise of a pulse signal flowing through the first line 31. According to such a configuration, if the first signal S1 is weakened, problems caused by the rise timing of a pulse signal can be adjusted by delaying the rise of the second signal S2.

In the present embodiment, the controller 12 becomes capable of receiving the second signal S2 after the first signal S1 rises to a predetermined level or more in at least one piece of processing. According to the configuration in the present embodiment, the second signal S2 can be made receivable also in the processing of the controller 12 as described above by, for example, completing the rise of the second signal S2 after the first signal S1 rises to a predetermined level or more.

Incidentally, the structure of the present embodiment is not limited to shifts of waveform timing based on a difference of lengths between the first line 31 and the second line 32 and may also be applied to resolve shifts of waveform timing due to insufficient margins resulting from other design causes or parameter changes (so-called mask changes of NAND) of products. The structure according to the present embodiment and the second and third embodiments described later is particularly effective in a semiconductor device in which high-speed performance of, for example, UHS-1, UHS-2, or class 10 or higher is realized.

### Second Embodiment

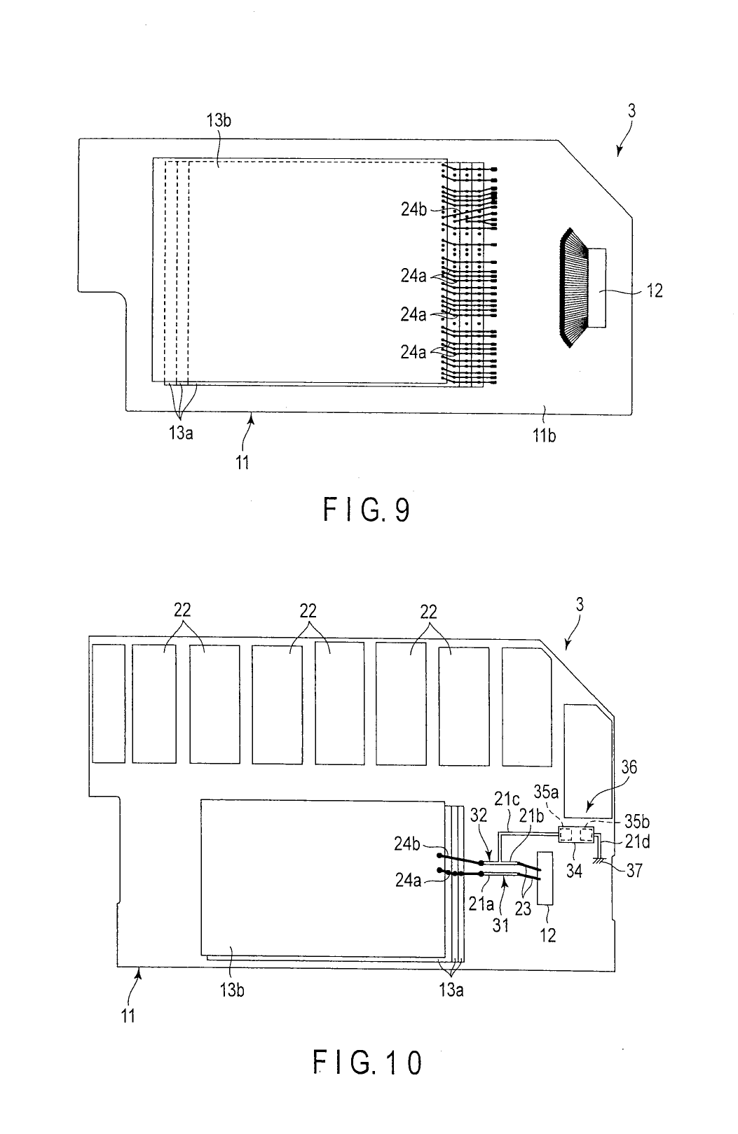

Next, a semiconductor device 1 according to the second embodiment will be described with reference to FIGS. 9 to 15. The same reference numerals are attached to elements having functions that are the same or similar to those in the first embodiment and the description thereof is omitted. In addition, elements other than those described below are the same as in the first embodiment.

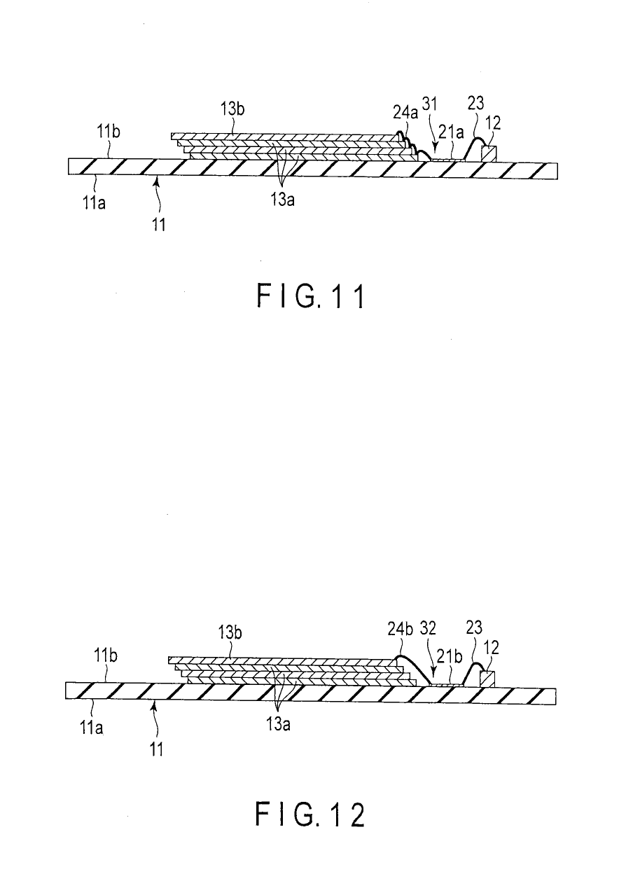

FIG. 9 shows a module 3 according to the present embodiment. FIG. 10 schematically shows the relationship between a controller 12 and a semiconductor chip 13. FIG. 11 schematically shows a first line 31 of a module 3. FIG. 12 schematically shows a second line 32 of the module 3. In FIGS. 10 to 12, for convenience of description, external terminals 22 and the controller 12 are depicted and shown on one surface of a board 11.

As shown in FIGS. 9 to 12, the semiconductor device 1 includes a plurality (e.g., four) of semiconductor chips 13. The semiconductor chips 13 are piled up each other on a second surface 11b of the board 11 to constitute, for example, a four-layer NAND laminated structure. Incidentally, the laminated structure of the semiconductor chips 13 may have less or more than four layers. The plurality of semiconductor chips 13 includes a plurality of first semiconductor chips 13a and a second semiconductor chip 13b distinguished for convenience of description.

The first semiconductor chips 13a are put on the second surface 11b of the board 11. The first semiconductor chips 13a include the semiconductor chip 13 closest to the board 11 among the plurality of semiconductor chips 13, for example. In the present embodiment, the semiconductor chips 13 include, for example, the three first semiconductor chips 13a. The second semiconductor chip 13b is put on the first semiconductor chip 13a from the opposite side of the board 11. The second semiconductor chip 13b is the semiconductor chip 13 to which a second line 32 described later is connected. In the present embodiment, the second semiconductor chip 13b is positioned in the top layer of the plurality of semiconductor chips 13. However, the second semiconductor chip is not limited to the semiconductor chip 13 positioned in the top layer.

As shown in FIGS. 9 to 12, a first line 31 (e.g., a first wire or first signal line) and the second line 32 (e.g., a second wire or second signal line) extend between the controller 12 and the second semiconductor chip 13b.

As shown in FIGS. 10 and 11, the first line 31 includes a wiring pattern 21a provided on the board 11 and a first bonding wire 24a. The first bonding wire 24a is connected from the wiring pattern 21a to the lowest-layer first semiconductor chip 13a and then connected to the second semiconductor chip 13b via the plurality of first semiconductor chips 13a successively. In other words, the first line 31 electrically connects the second semiconductor chip 13b and the controller 12 via at least the one first semiconductor chip 13a.

As shown in FIGS. 10 and 12, the second line 32 includes a wiring pattern 21b provided on the board 11 and a second bonding wire 24b. The second bonding wire 24b is directly connected from the wiring pattern 21b to the second semiconductor chip 13b. That is, the second bonding wire 24b is not connected to the first semiconductor chip 13a. The second line 32 electrically connects the second semiconductor chip 13b and the controller 12 by bypassing the first semiconductor chips 13a.

As shown in FIGS. 9 to 12, a signal flowing through the first line 31 goes via the first semiconductor chips 13a and thus, a waveform thereof is more likely to be weakened than that of a signal flowing through the second line 32. For example, a pulse signal flowing through the first line 31 has a gentler rise than a pulse signal flowing through the second line 32.

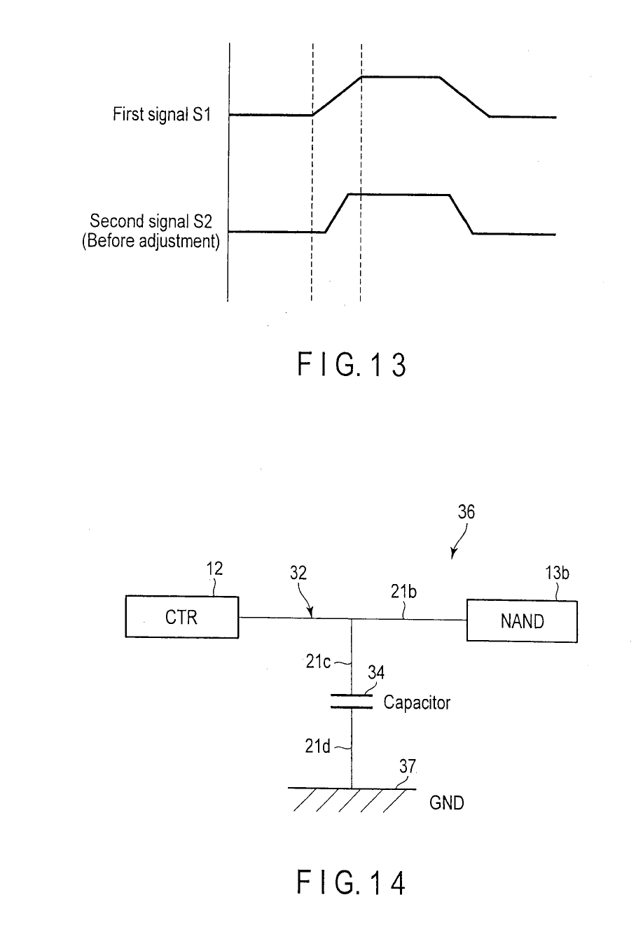

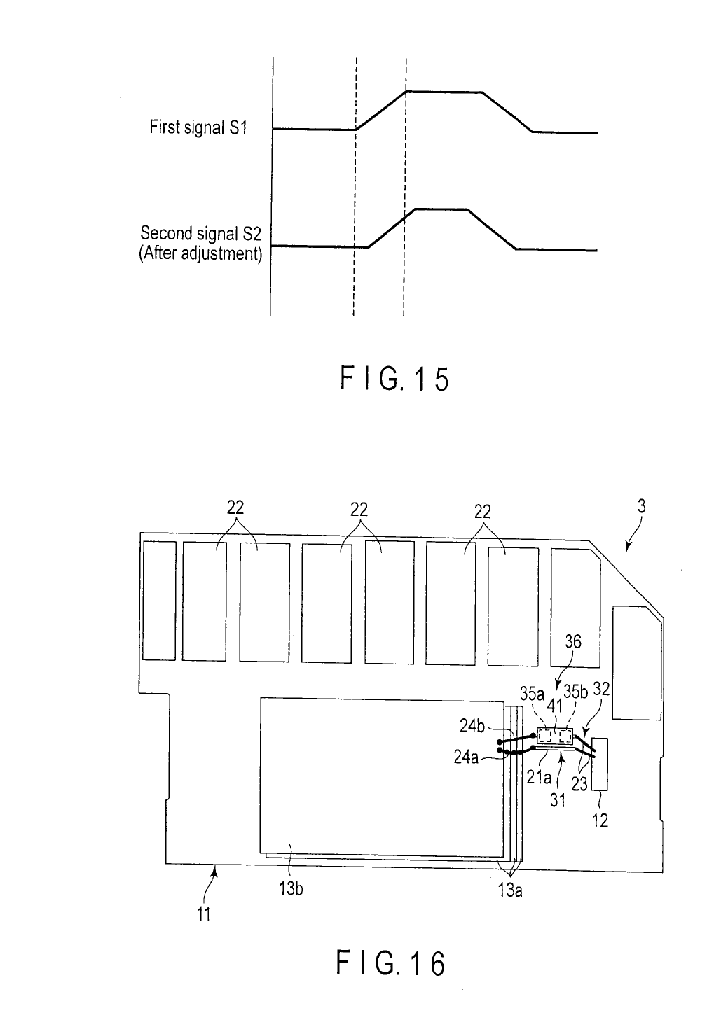

FIG. 13 shows an example of waveforms of signals when a capacitor 34 described later is not mounted. A first signal S1 is an example of a signal input into the second semiconductor chip 13b after flowing through the first line 31 from the controller 12. A second signal S2 is an example of a signal input into the second semiconductor chip 13b after flowing through the second line 32 from the controller 12. Incidentally, FIGS. 13 and 15 show waveforms of the first signal S1 and the second signal S2 in the instant of being input into the second semiconductor chip 13b.

As shown in FIG. 13, the signal S1 going through the first semiconductor chip 13a is weakened in the process of passing through the first semiconductor chip 13a. On the other hand, the signal S2 directly sent to the second semiconductor chip 13b becomes a relatively sharp pulse signal.

That is, when the capacitor 34 is not mounted, a rise of the first signal S1 (e.g., a first pulse signal) is gentler than a rise of the second signal (e.g., a second pulse signal). Therefore, even if the second signal S2 starts a rise in the timing substantially simultaneously with or delayed from a start of rise of the first signal S1, the rise of the second signal S2 may be completed in the timing before the rise of the first signal S1 is completed.

The board 11 in the present embodiment includes, like in the first embodiment, pads 35a, 35b. The pads 35a, 35b are to be electrically connected to the second line 32 and to be a part of a waveform adjustment circuit 36 that makes a waveform of the signal S2 flowing through the second line 32 more similar to a waveform of the signal S1 flowing through the first line 31.

FIG. 14 shows an example of a waveform adjustment circuit 36 according to the present embodiment. As shown in FIGS. 10 and 14, the pads 35a, 35b can receive the capacitor 34 mounted thereon as an option when a waveform adjustment (e.g., a waveform timing adjustment) is needed. The pads 35a, 35b are so-called spare pads and remain in the product as empty pads when the waveform adjustment is not needed.

As shown in FIGS. 10 and 14, the one pad 35a is connected in parallel between the controller 12 and the second semiconductor chip 13b. That is, the pad 35a is electrically connected to the second line 32 via a wiring pattern 21c. On the other hand, the other pad 35b is electrically connected to a ground 37 via another wiring pattern 21d.

The capacitor 34 is connected in parallel between the controller 12 and the second semiconductor chip 13b via the pads 35a, 35b. The capacitor 34 makes the rise of a pulse signal flowing through the second line 32 gentler. That is, the capacitor 34 makes a rise gentler such that the rise of the pulse signal flowing through the second line 32 is substantially simultaneous with or delayed from a rise of a pulse signal flowing through the first line 31.

FIG. 15 shows an example of waveforms of signals when the capacitor 34 is mounted. In the present embodiment, if, as shown in FIG. 15, the second signal S2 starts to rise in the timing substantially simultaneous with or delayed from a start of rise of the first signal S1, the rise of the second signal S2 is completed in the timing substantially simultaneous with or delayed from the completion of rise of the first signal S1.

When the first signal S1 and the second signal S2 are sent from the controller 12 to the second semiconductor chip 13b, the second semiconductor chip 13b becomes capable of receiving a pulse signal input from the second line 32 after a pulse signal input from the first line 31 rises to a predetermined level or more in at least one piece of processing.

In the present embodiment, the rise timing of the second signal S2 is adjusted by the waveform adjustment circuit 36. Thus, the second semiconductor chip 13b first checks whether the first signal S1 is input and then becomes capable of receiving the second signal S2. The second semiconductor chip 13b receives the second signal S2 in this state and performs processing based on the second signal S2.

Similarly, when the first signal S1 and the second signal S2 are sent from the second semiconductor chip 13b to the controller 12, the controller 12 becomes capable, of receiving a pulse signal input from the second line 32 after a pulse signal input from the first line 31 rises to a predetermined level or more in at least one piece of processing. In the present embodiment, the rise timing of the second signal S2 is adjusted by the waveform adjustment circuit 36. Thus, the controller 12 first checks whether the first signal S1 is input and then becomes capable of receiving the second signal S2. The controller 12 receives the second signal S2 in this state and performs processing based on the second signal S2.

Next, the operation of the semiconductor device 1 according to the present embodiment will be described.

The semiconductor device 1 according to the present embodiment has, like in the first embodiment, the pads 35a, 35b to be a part of the waveform adjustment circuit 36 provided on the board 11 in advance. Then, when the semiconductor device 1 does not operate as designed due to signal timing shifts or the like, the waveform adjustment circuit 36 can be added by mounting an additional component (e.g., the capacitor 34) on the pads 35a, 35b. By providing the waveform adjustment circuit 36, the timing of the signal S2 flowing through the second line 32 can be adjusted and the semiconductor device 1 can be caused to operate as designed.

In the present embodiment, the second semiconductor chip 13b and/or controller 12 becomes capable of receiving the second signal S2 after the first signal S1 rises to a predetermined level or more in at least one piece of processing. According to the configuration in the present embodiment, the second signal S2 can be made receivable also in the processing of the second semiconductor chip 13b and/or controller 12 as described above by, for example, completing the rise of the second signal S2 after the first signal S1 rises to a predetermined level or more.

A signal flowing through the first line 31 is more weakened with an increasing number of layers of the first semiconductor chips 13a. Therefore, the structure according to the present embodiment is particularly effective in the semiconductor device 1 having a laminated structure of the semiconductor chip 13 of, for example, four layers or more.

### Third Embodiment

Next, a semiconductor device 1 according to the third embodiment will be described with reference to FIGS. 16 to 21. The same reference numerals are attached to elements having functions that are the same or similar to those in the first and second embodiments and the description thereof is omitted. In addition, elements other than those described below are the same as in the second embodiment.

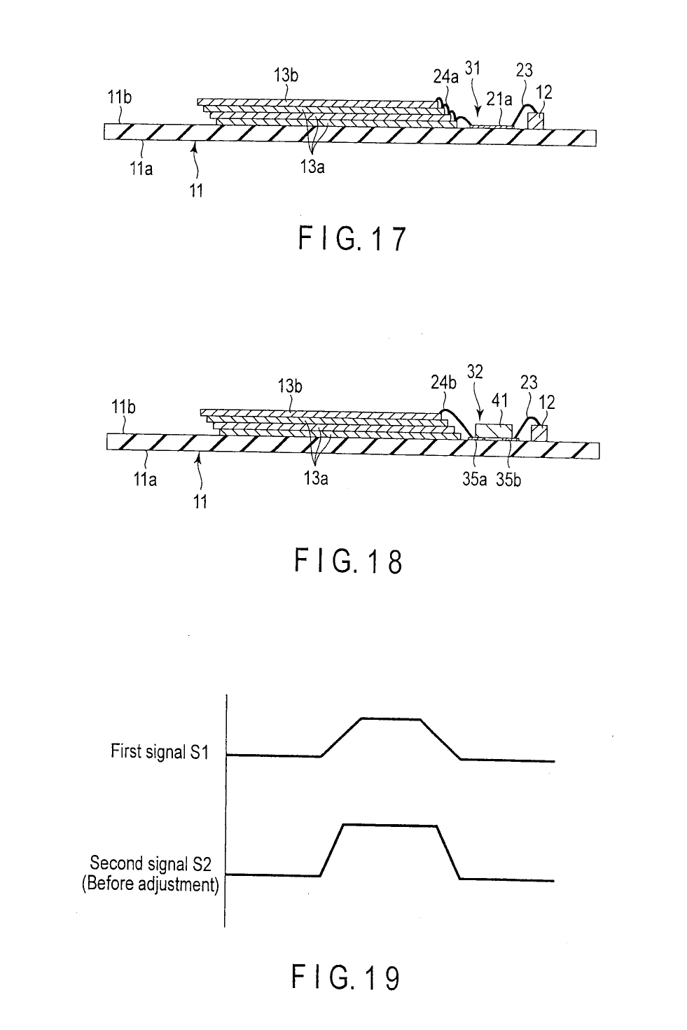

FIG. 16 schematically shows the relationship between a controller 12 and a semiconductor chip 13. FIG. 17 schematically shows a first line 31 of a module 3. FIG. 18 schematically shows a second line 32 of the module 3. In FIGS. 16 to 18, for convenience of description, external terminals 22 and the controller 12 are depicted and shown on one surface of a board 11.

As shown in FIGS. 16 to 18, the semiconductor device 1 includes, like in the second embodiment, a plurality (e.g., four) of semiconductor chips 13. The semiconductor chips 13 are piled up each other on a second surface 11b of the board 11. The semiconductor chips 13 include a plurality of first semiconductor chips 13a and a second semiconductor chip 13b. A first line 31 (e.g., a first wire or first signal line) and a second line 32 (e.g., a second wire or second signal line) extend between the controller 12 and the second semiconductor chip 13b.

As shown in FIGS. 16 to 18, a signal flowing through the first line 31 goes via the first semiconductor chips 13a and thus, a waveform thereof is more likely to be weakened than that of a signal flowing through the second line 32. For example, a pulse signal flowing through the first line 31 has a smaller amplitude than a pulse signal flowing through the second line 32.

FIG. 19 shows an example of waveforms of signals when a resistor 41 described later is not mounted. A first signal S1 is an example of a signal input into the second semiconductor chip 13b after flowing through the first line 31 from the controller 12. A second signal S2 is an example of a signal input into the second semiconductor chip 13b after flowing through the second line 32 from the controller 12. Incidentally, FIGS. 19 and 21 show waveforms of the first signal S1 and the second signal S2 in the instant of being input into the second semiconductor chip 13b.

As shown in FIG. 19, the signal S1 going through the first semiconductor chips 13a is weakened in the process of passing through the first semiconductor chip 13a. Therefore, when the resistor 41 is not mounted, an amplitude of the first signal S1 becomes smaller than an amplitude of the second signal S2.

The board 11 in the present embodiment includes, like in the second embodiment, pads 35a, 35b. The pads 35a, 35b are to be electrically connected to the second line 32 and to be a part of a waveform adjustment circuit 36 that makes a waveform of the signal S2 flowing through the second line 32 more similar to a waveform of the signal S1 flowing through the first line 31.

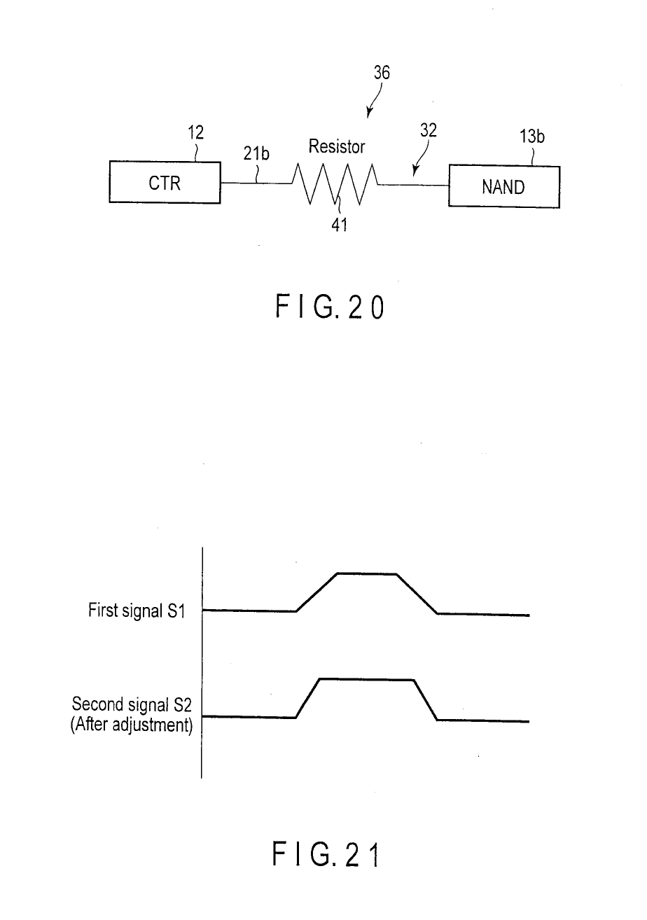

FIG. 20 shows an example of a waveform adjustment circuit 36. As shown in FIGS. 16 and 20, the pads 35a, 35b can receive the resistor 41 mounted thereon as an option when a waveform adjustment (e.g., a waveform timing adjustment) is needed. The pads 35a, 35b are so-called spare pads. When the waveform adjustment is not needed, the pads 35a, 35b are electrically connected each other by, for example, a jumper (e.g., zero-ohm register, etc).

As shown in FIGS. 16 and 20, the one pad 35a is connected in series to the connector 12 via a wiring pattern 21b. The other pad 35b is connected in series to the second semiconductor chip 13b via the wiring pattern 21b. That is, the pads 35a, 35b are provided halfway through the second line 32.

When a waveform adjustment is needed, the waveform adjustment circuit 36 is added by the resistor 41 being mounted on the pads 35a, 35b. An example of the waveform adjustment circuit 36 is configured by the pads 35a, 35b and the resistor 41.

The resistor 41 is connected in series between the controller 12 and the second semiconductor chip 13b via the pads 35a, 35b. The resistor 41 makes an amplitude of a pulse signal (i.e., the second signal S2) flowing through the second line 32 smaller.

FIG. 21 shows an example of waveforms of signals when the resistor 41 is mounted. In the present embodiment, as shown in FIG. 21, the resistor 41 makes an amplitude of a pulse signal flowing through the second line 32 smaller such that the amplitude thereof is more similar to an amplitude of a pulse signal flowing through the first line 31.

Next, the operation of the semiconductor device 1 according to the present embodiment will be described.

The semiconductor device 1 according to the present embodiment has, like in the first embodiment, the pads 35a, 35b provided on the board 11 in advance. Then, when the semiconductor device 1 does not operate as designed due to, for example, a significant difference of amplitudes of a plurality of signals, the waveform adjustment circuit 36 can be added by mounting an additional component (e.g., the resistor 41) on the pads 35a, 35b. By providing the waveform adjustment circuit 36, the amplitude of the signal S2 flowing through the second line 32 can be adjusted and the semiconductor device 1 can be caused to operate as designed.

In the configuration of the first embodiment, the resistor 41 may be connected in series between a second external terminal 22b and the controller 12 in place of the capacitor 34 or in addition to the capacitor 34. According to such a configuration, the amplitude of a signal flowing through the second line 32 can be made smaller.

In the foregoing, the first to third embodiments have been described, but the present invention is not limited to the above embodiments. Elements in each embodiment can be implemented by appropriate alterations, substitutions, or combinations.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a board comprising a first external terminal and a second external terminal;
a controller on the board;
a first line extending between the first external terminal and the controller;
a second line extending between the second external terminal and the controller; and
a pad to be electrically connected to the second line and to be a part of a waveform adjustment circuit that makes a waveform of a signal flowing through the second line more similar to a waveform of a signal flowing through the first line.

2. The device of claim 1, wherein
the pad is to receive a capacitor that makes a rise of a pulse signal flowing through the second line gentler.

3. The device of claim 2, wherein
the capacitor makes the rise of the pulse signal gentler such that the rise of the pulse signal flowing through the second line becomes substantially simultaneous with or delayed from a rise of a pulse signal flowing through the first line.

4. The device of claim 3, wherein
the controller becomes capable of receiving a pulse signal input from the second line after a pulse signal input from the first line rises to a predetermined level or more in at least one piece of processing.

5. The device of claim 4, wherein
the first line is longer than the second line and when the capacitor is not mounted, the rise of the pulse signal flowing through the first line is gentler than the rise of the pulse signal flowing through the second line and the capacitor is mounted on the pad.

6. A semiconductor device comprising:
a board;
a controller on the board;
a first semiconductor chip on the board;
a second semiconductor chip on the first semiconductor chip, the first semiconductor chip being between the board and the second semiconductor;
a first line electrically connecting the second semiconductor chip and the controller via the first semiconductor chip;
a second line electrically connecting the second semiconductor chip and the controller; and
a pad to be electrically connected to the second line and to be a part of a waveform adjustment circuit that makes a waveform of a signal flowing through the second line more similar to a waveform of a signal flowing through the first line.

7. The device of claim 6, wherein
the pad is to receive a capacitor that makes a rise of a pulse signal flowing through the second line gentler.

8. The device of claim 7, wherein
the capacitor makes the rise of the pulse signal gentler such that the rise of the pulse signal flowing through the second line becomes substantially simultaneous with or delayed from a rise of a pulse signal flowing through the first line.

9. The device of claim 8, wherein
the second semiconductor chip becomes capable of receiving a pulse signal input from the second line after a pulse signal input from the first line rises to a predetermined level or more in at least one piece of processing.

10. The device of claim 9, wherein
when the capacitor is not mounted, the rise of the pulse signal flowing through the first line is gentler than the rise of the pulse signal flowing through the second line and
the capacitor is mounted on the pad.

11. The device of claim 8, wherein
the controller becomes capable of receiving a pulse signal input from the second line after a pulse signal input from the first line rises to a predetermined level or more in at least one piece of processing.

12. The device of claim 6, wherein
the pad is to receive a resistor that makes an amplitude of a pulse signal flowing through the second line smaller.

13. The device of claim 12, wherein
the resistor makes the amplitude of the pulse signal smaller such that the amplitude of the pulse signal flowing through the second line more similar to an amplitude of a pulse signal flowing through the first line.
